(19) United States
(12) Patent Application Publication
(10) Pub. No.: US 2002/0142626 A1
(43) Pub. Date: Oct. 3, 2002

(54) Electrical interconnect structure

(76) Inventor: Palmer D. Smeltz JR., Fleetwood, PA (US)

Correspondence Address: VOLENTINE FRANCOS, P.L.L.C., SUITE 150, 12200 SUNRISE VALLEY DRIVE, RESTON, VA, 20191, US

(21) Appl. No.: 10/100,266

(22) Filed: Mar. 18, 2002

Related U.S. Application Data
(60) Provisional application No. 60/276,138, filed on Mar. 16, 2001.

(51) Int. Cl. H05K 1/00

(52) U.S. Cl. 439/65

(57) ABSTRACT

In accordance with an exemplary embodiment of the present invention, an electrical apparatus includes a pedestal having at least one first electrical contact at a first level, and at least one second electrical contact at a second level, which is at a lower height than the first level. According to one exemplary embodiment, at least one third electrical contact electrically connects the first contact to the second contact, and is oriented substantially perpendicularly to the first and second contacts.

Acccording to another exemplary embodiment of the present invention, an optoelectronic package includes an optoelectronic device disposed over a substrate. The package also includes interfacing electrically circuitry disposed outside of the package; and an electrical interconnect having a pedestal which has at least one first electrical contact at a first level, and at least one second electrical contact at a second level, which is at a lower height than the first level. The package also includes at least one third electrical contact which electrically connects the first contact to the second contact, and is oriented substantially perpendicularly to the first and second contacts, wherein the interfacing electrical circuitry is disposed at the second level.

### CROSS-REFERENCE TO RELATED APPLICATIONS

The present application claims priority under 35 USC §119(e) from U.S. Provisional Application Serial No. 60/276,138, filed Mar. 16, 2001. The disclosure of this provisional application is specifically incorporated herein by reference and for all purposes.

### FIELD OF THE INVENTION

The present invention relates generally to an electrical interconnect, and particularly to a structure for electrically connecting device having differing height locations.

### BACKGROUND OF THE INVENTION

The increasing demand for high-speed voice and data communications has led to an increased reliance on optical communications, particularly optical fiber communications. The use of optical signals as a vehicle to carry information at high speeds is preferred in many instances to carrying information at other electromagnetic wavelengths/frequencies in media such as microwave transmission lines, coaxial cable lines and twisted-pair transmission lines. Advantages of optical media are, among others, higher bandwidth, greater immunity to electromagnetic interference, and lower propagation loss. In fact, it is common for high-speed optical communications systems to have signal rates in the range of approximately several gigabits per second (Gbit/sec) to approximately several tens of Gbit/sec, and higher. However, while the optical communication system is useful for the transmission of information, ultimately the optical signals may have to be converted to electrical signals (and vice-versa). As such, an electrical interface is required between the optical device(s) and the electrical device(s).

One commonly used structure in optical communications is the discrete package device. Often, the discrete package device includes at least one discrete optoelectronic component, which is typically coupled optically to an optical waveguide at one end, and electrically connected to electronic circuitry at another. Often the packaging requires the optoelectronic device(s) and the electrical circuit to be at differing heights. For example the optoelectronic device is often elevated relative to the electronic circuitry to foster acceptable coupling between the device, the waveguide and any passive optical components therebetween. For this and other reasons external wire and/or ribbon bonds are needed to effect the electrical connection between the electrical and the optoelectronic devices. Unfortunately, this type of interconnect has an uncontrolled impedance, making impedance matching between the optoelectronic and electrical devices difficult.

As is well known to one of ordinary skill in the art, impedance matching is necessary to assure good performance and to assure signal quality. For example, if the devices and transmission lines are not impedance-matched, undesirable back-reflections may result, and these back reflections may significantly interfere with the effective transmission of high-speed signals. For example, reflections due to impedance mismatch may result in interference of the signal carried to/from the optoelectronic device causing attenuation and/or distortion of the signal, and, ultimately transmission error. The problems associated with impedance matching are pronounced in high frequency applications.

Moreover, the use of wire bonds may contribute to a parasitic inductance, which can significantly degrade the speed of the signal which can be transmitted to and from the optoelectronic device.

Accordingly, what is needed is a packaging scheme which fosters a high-performance electrical interface by overcoming the shortfalls of the conventional art described above.

### SUMMARY OF THE INVENTION

In accordance with an exemplary embodiment of the present invention, an electrical apparatus includes a pedestal having at least one first electrical contact at a first level, and at least one second electrical contact at a second level, which is at a lower height than the first level. According to one exemplary embodiment, at least one third electrical contact electrically connects the first contact to the second contact, and is oriented substantially perpendicularly to the first and second contacts.

Acccording to another exemplary embodiment of the present invention, an optoelectronic package includes an optoelectronic device disposed over a substrate. The package also includes interfacing electrically circuitry disposed outside of the package; and an electrical interconnect having a pedestal which has at least one first electrical contact at a first level, and at least one second electrical contact at a second level, which is at a lower height than the first level. The package also includes at least one third electrical contact which electrically connects the first contact to the second contact, and is oriented substantially perpendicularly to the first and second contacts, wherein the interfacing electrical circuitry is disposed at the second level.

### BRIEF DESCRIPTION OF THE DRAWINGS

The invention is best understood from the following detailed description when read with the accompanying drawing figures. It is emphasized that the various features are not necessarily drawn to scale. In fact, the dimensions may be arbitrarily increased or decreased for clarity of discussion. In addition, it is noted that like reference numerals are used to designate like elements throughout the drawings.

FIG. 1 is a side view of an optoelectronic package structure according to an exemplary embodiment of the present invention.

FIG. 2 is an exploded view of the electrical interconnect structure of FIG. 1 according to an exemplary embodiment of the present invention.

FIG. 3 is a cross-sectional view of an electrical interconnect structure according to an exemplary embodiment of the present invention.

### DEFINITIONS

For the purposes of the present disclosure, the term “on” may mean directly on top of a layer; alternatively “on” may mean “over,” with one or more intervening layers. In addition, for the purposes of the present disclosure, the term “optical device” means active optical device, or optoelectronic device; whereas the term passive optical element takes its customary meaning.

### DETAILED DESCRIPTION

In the following detailed description, for purposes of explanation and not limitation, exemplary embodiments disclosing specific details are set forth in order to provide a thorough understanding of the present invention. However, it will be apparent to one having ordinary skill in the art having had the benefit of the present disclosure, that the present invention may be practiced in other embodiments that depart from the specific details disclosed herein. Moreover, descriptions of well-known devices, methods and materials may be omitted so as to not obscure the description of the present invention.

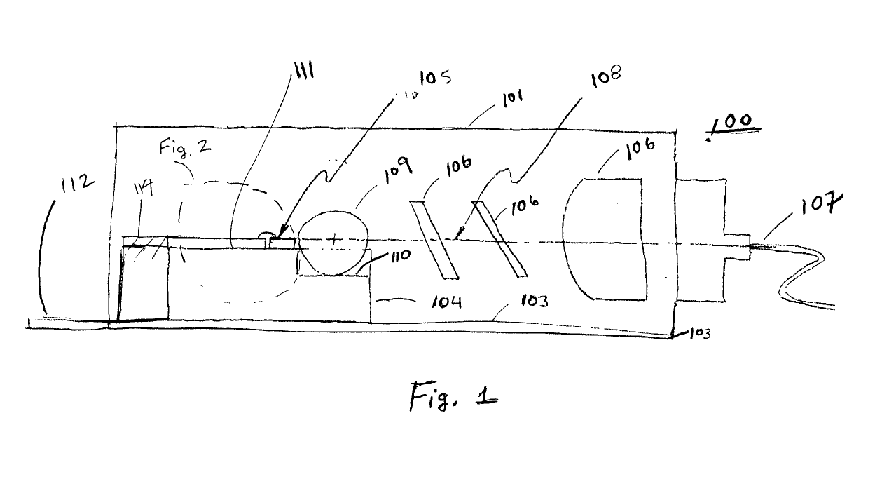

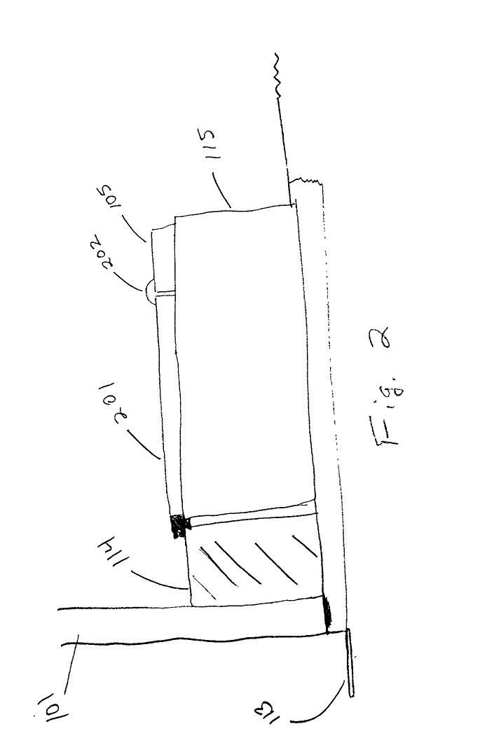

FIG. 1 is a side cross-sectional view of an optoelectronic package 100 in accordance with an exemplary embodiment of the present invention. A package housing 101 has a lower surface 103 over which a substrate 104 is disposed. The substrate 104 has an optical device 105 disposed thereover. The optical device 105 is illustratively a laser or other light emitting device. Of course, this is merely illustrative and it is clear that other active optical devices could be packaged and benefit from the present invention.

The optical device is optically coupled to a waveguide such as an optical fiber 107. Passive optical elements 106 may be lens elements, isolators and/or other devices which foster coupling between the optical device 105 and the optical fiber 107. Such devices are well within the purview of the artisan of ordinary skill who has had the benefit of the present disclosure. As can be readily appreciated from a review of FIG. 1, to ensure proper coupling between the optical device 105 and the optical fiber 107, the optical device 105 must be aligned with the optical path (optic axis) 108 of the passive elements 106. This requires the suitable location of the lens element 109, which is illustratively a ball lens. The lens element 109 must be located at a lower level on a notch 110 to enable coupling of the optical device. Accordingly, the top surface 111 of the substrate 104 is elevated relative to the notch 110. Moreover, the need for the alignment of the lens element 109, the passive elements 106 and the optical device 105 results in the elevation of the optical device 105 relative to the lower surface 103 of the package housing 101 to which electrical connections to electrical circuitry 112, such as signal transmission lines, are made. To wit, it is necessary to locate and align the various elements needed for optical coupling on a common level. In typical optoelectronic packages, this has created the needs for wirebonds and/or other devices which adversely impact electrical performance, particularly at transmission speeds of 10 GHz and greater.

The electrical interconnect 114 in accordance with an exemplary embodiment of the present facilitates the electrical connection between the optical device 105 and the electrical circuitry 112, by providing a smooth electrical transition across over the disparate levels (heights) between the optical device 105 disposed over the top surface and the electrical circuitry 1 12 disposed at the level of the lower surface 103.

As will become clearer as the present description proceeds, by virtue of the electrical interconnect 114, wire bonds/ribbon bonds and via structures which are used in conventional structures are eliminated in, thereby improving the electrical performance of signal transmission between the electrical device 105 and the electrical circuitry 112.

FIG. 2 shows the electrical interconnect 114 in magnified view. The interconnect is electrically connected to electrical circuitry 201, which is illustratively microstrip transmission line (microstripline). This electrical connection may be made by soldering or other standard technique. Only one interconnection of relatively short ribbon(s) or wires 116 is required to make the electrical connection between the device 105 and the circuitry. This is in clear contrast to conventional interconnection techniques that require several interfaces of wires/ribbons, some of which are lengthy, to physically complete the interconnection from the device to the circuitry. It is these multiple interfaces in conventional interconnection schemes, which create uncontrolled impedances in the transmission line resulting in subsequent reflections thereby limiting the total high speed performance.

It is also noted that the electrical interconnect 114 also makes an electrical connection to the interior wall of the package at the same level as the outside circuitry 112 thereby allowing for a controlled impedance line through the wall of the package. This substantially eliminates the uncontrolled impedance vias in the package wall and subsequent reflections which limit the high speed performance in conventional packaging schemes.

As can be readily appreciated from a review of FIGS. 1 and 2, and the accompanying descriptions thereof, the electrical interconnect 114 enables the electrical connection from an optical device/electrical circuitry (e.g. optical device 105/electrical circuitry 201) at one level to electrical circuitry 112 at another level by cooperative engagement between the two levels, and by making a perpendicular electrical connection to both of these levels.

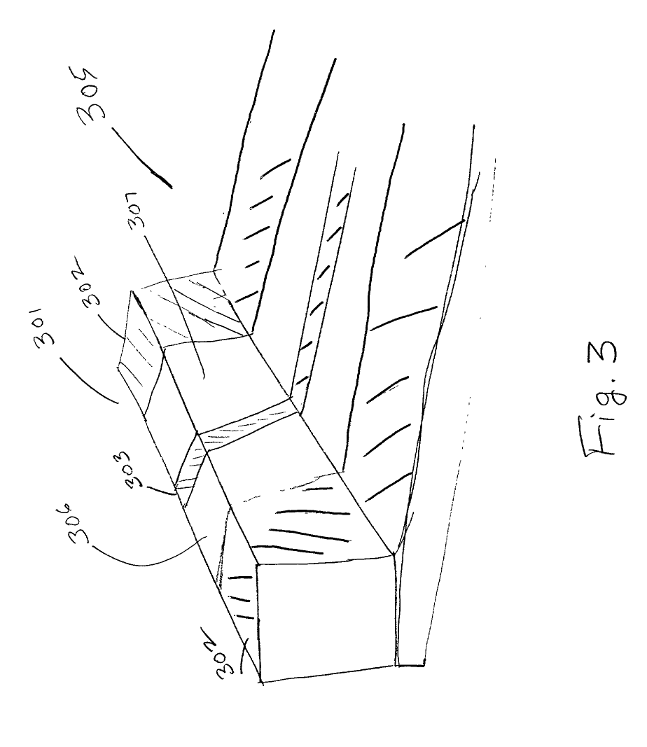

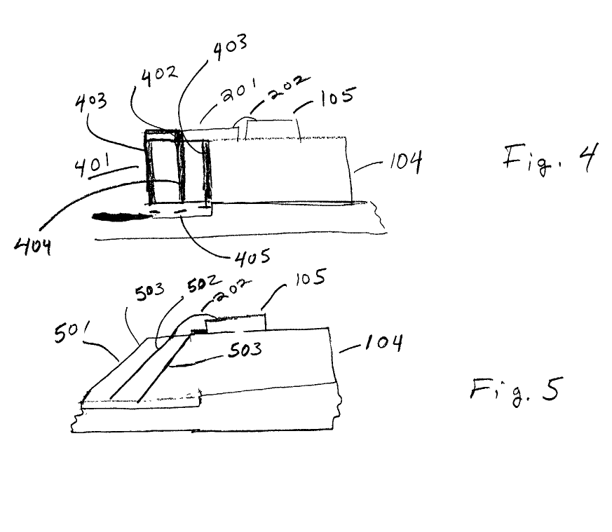

FIG. 3 shows an electrical interconnect 301 in accordance with an exemplary embodiment of the present invention. The electrical interconnect 301 illustratively has microstripline formed thereon, with ground planes 302 and signal line 303. The microstripline is of the electrical interconnect 301 is aligned and electrically connected to another microstripline 305. In the present exemplary embodiment, the microstripline 305 may be the electrical circuitry of an optical subassembly, such as electrical circuitry 112 of FIG. 1. Of course the use of microstripline is merely illustrative, and other types of signal transmission lines and/or electrical circuitry may be used in this capacity.

The microstripline on top surface of the electrical interconnect 301 is used to make the electrical connection to the optical device (not shown in FIG. 3), which is elevated relative to (at a higher level than) the microstripline 305; and the microstripline on the side surface 307 of the electrical interconnect provides the perpendicular electrical path between the two levels. For example, the electrical interconnect 301 may be disposed used in a configuration such as shown in FIGS. 1 and 2, thereby making the electrical connection between the optical device 105 at one level and the electrical circuitry 112 at another level by making the perpendicular electrical path.

In accordance with an exemplary embodiment of the present invention the electrical interconnect may be of virtually any dielectric material containing various forms of impedance matching circuitry (but not necessarily limited to) such as a stripline, a microstripline, a coplanar stripline, a grounded coplanar stripline, or a coaxial transmission line. Furthermore, the electrical interconnect may be fabricated by standard techniques utilizing both rigid or flexible dielectric materials.

By virtue of the present invention, the frequency performance, which is limited in conventional discrete package optoelectronic devices to on the order of 10 GHz or less, is significantly improved. To this end, the high-frequency transmission range of the invention of the present disclosure may be above approximately 10 GHz and up to approximately 50 GHz.

Moreover, as described above, impedance matching may be problematic in conventional discrete package optoelectronic devices using wire bonds/ribbon bonds. According to the invention of the present disclosure, the electrical distance (or length) of the impedance discontinuity between the transmission is significantly reduced compared to conventional structures. To wit, the only impedance discontinuity is in the embodiment in which a relatively short wire bond 202 is used to connect the optical device 105 to the microstripline 201 as shown in FIG. 2. In all other portions of the electrical path between the electrical circuitry 112 and the optical device 105, impedance matching techniques may be used. These include, but are not limited to the use of transmission lines from the optical device 105 to the circuitry, including of course the electrical interconnect 114, 301, which is impedance matched as described above. In addition, miniature microwave resistors, capacitors and/or inductors may be placed or fabricated on the electrical interconnect 114, 301, and/or on the electrical path.

It is noted that to this point the electrical interconnect according to exemplary embodiments of the present invention have been focused on effecting an electrical connection having improved performance, between an optical device and an electrical circuitry, where the electrical circuitry and the optical device are at differing heights/levels. Of course, the electrical interconnect of the present invention may be used in other applications as well. For example, the electrical interconnect may be used to provide a substantially smooth electrical interface between two electrical devices or between an electrical device and electrical circuitry. This is particularly beneficial when the transmission speeds are 10 GHz, and greater. Such applications will be readily apparent to one having ordinary skill in the art who has had the benefit of the present disclosure.

Moreover, as mentioned briefly above, the electrical interconnect in accordance with an exemplary embodiment of the present invention may be adapted to effect an electrical connection via a transmission line that is coaxial. Such an interconnect is shown in FIG. 4. In the exemplary embodiment shown in FIG. 4, an electrical interconnect 401 is illustratively cylindrical in shape having a ground conductor 403 that is disposed circumferentially about the interconnect 401. The signal conductor 404 illustratively is disposed along the central axis of the cylinder. The electrical circuitry 201 is substantially identical to that described previously, but is adapted to connect the respective signal conductors and ground conductors. Illustratively, a via 403 effects the connection to the signal conductor 404. Finally, electrical conductors 405 enable the electrical connect to the electrical circuitry (not shown) outside the package. Of course, it is possible that the connection from circuitry outside the package could be effected via a coaxial connector (e.g., an SMA connector), which may be connected to the electrical interconnect 401.

In the exemplary embodiments described thus far, the electrical interconnects that foster a substantially uninterrupted transmission of the correct impedance from the optical device to the interfacing electrical circuitry have been discrete elements. However, it is within the purview of the present invention that the electrical interconnect is an integrated element. As shown in FIG. 5, an electrical interconnect 501 having a signal conductor 502 and ground conductors 503 may be integrally formed from the substrate 104 or similar structure. The function and type of transmission line used in this embodiment is substantially identical to that described in conjunction with the exemplary embodiments above. Moreover, because the substrate 104 is of a material well known in the art, the design and processing of the electrical interconnect 501 is within the purview of one having ordinary skill in the art who has had the benefit of the present disclosure.

The invention having been described in detail, it will be readily apparent to one having ordinary skill in the art that the invention may be varied in a variety of ways. Such variations are not to be regarded as a departure from the scope of the invention. All such modifications as would be obvious to one of ordinary skill in the art, having had the benefit of the present disclosure, are intended to be included within the scope of the appended claims.

We claim:

1. An electrical interconnect, comprising:
a pedestal having at least one first electrical contact at a first level, and at least one second electrical contact at a second level, which is at a lower height than said first level;
and at least one third electrical contact which electrically connects said at least one first contact to said at least one second contact, and is oriented substantially perpendicularly to said first and second contacts.

2. An electrical interconnect as recited in claim 1, wherein the interconnect is substantially rectangular in cross-section.

3. An electrical interconnect as recited in claim 1, wherein the interconnect is substantially square in cross-section.

4. An electrical interconnect as recited in claim 1, wherein said first, said second, and said third electrical contacts are transmission lines.

5. An electrical interconnect as recited in claim 1, wherein said transmission lines are chosen from the group consisting essentially of: microstripline; stripline; coplanar stripline; grounded coplanar stripline; and coaxial transmission lines.

6. An electrical initerconnect as recited in claim 1, wherein said pedestal is a discrete element.

7. An electrical interconnect as recited in claim 1, wherein said pedestal is an integral part of a substrate over which a device is disposed.

8. An electrical interconnect as recited in claim 1, wherein said electrical interconnect connects an optoelectronic device to interfacing electrical circuitry.

9. An electrical interconnect as recited in claim 8, wherein the electrical interconnect provides substantially uninterrupted transmission of the correct impedance from said optical device to the interfacing electrical circuitry.

10. An electrical interconnect as recited in claim 1, wherein the electrical interconnect electrically connects one electronic device to another electronic device.

11. An electrical interconnect as recited in claim 8, wherein said optoelectronic device is disposed in a package, and said interfacing electrical circuitry is outside of said package.

12. An optoelectronic package, comprising:
An optoelectronic device disposed over a substrate;
Interfacing electrically circuitry disposed outside of said package;
An electrical interconnect having a pedestal which has at least one first electrical contact at a first level, and at least one second electrical contact at a second level, which is at a lower height than the first level; and
at least one third electrical contact which electrically connects the first contact to the second contact, and is oriented substantially perpendicularly to the first and second contacts, wherein said interfacing electrical circuitry is disposed at said second level.

13. An optoelectronic package as recited in claim 12, wherein said first, said second, and said third electrical contacts are transmission lines.

14. An optoelectronic package as recited in claim 13, wherein said transmission lines are chosen from the group consisting essentially of: microstripline; stripline; coplanar stripline; grounded coplanar stripline; and coaxial transmission lines.

15. An optoelectronic package as recited in claim 12, wherein said electrical interconnect provides substantially uninterrupted transmission of the correct impedance from said optical device to the interfacing electrical circuitry.
